(19) United States
(12) Patent Application Publication
(10) Pub. No.: US 2008/0003956 A1
(43) Pub. Date: Jan. 3, 2008

(54) Apparatus and method for FM transmitting audio at optimal power levels

(76) Inventors: Paul Stanley Rutkowski, Carmel, IN (US); Sin Hui Cheah, Carmel, IN (US)

Correspondence Address: THOMSON LICENSING LLC, Two Independence Way, Suite 200, PRINCETON, NJ, 08540, US

(21) Appl. No.: 11/478,495

(22) Filed: Jun. 29, 2006

(51) Int. Cl. H04B 1/02; H05K 11/02; H04B 1/06

(52) U.S. Cl. 455/91; 455/345

(57) ABSTRACT

A compressed digital music adapting apparatus for vehicles is described, which includes a cigarette-lighter power port and an FM modulator/transmitter. The FM modulator/transmitter modulates compressed digital music from a digital music player and then transmits the modulated music to an FM receiver at a higher radiated power level when the apparatus is operating in a vehicle than when the apparatus is operated such that the compressed digital music is broadcasted outside the vehicle.

### CROSS REFERENCE TO RELATED APPLICATIONS

The present application is related to concurrently filed patent applications bearing applicant docket numbers PU060059 and PU060107.

### FIELD OF THE INVENTION

The present invention relates to a portable audio device having a low power FM transmitter, and more particularly, to a compressed digital music transmitting apparatus having adaptive RF power output.

### BACKGROUND OF THE INVENTION

Due to the rapid development of the Internet and the multimedia industry and also to the insatiable human desire to be entertained, various kinds of music storage devices and broadcast systems have continued to emerge over the years. Technology has evolved from phonographic discs and phonographs, and magnetically recorded tapes and magnetic recorders in the early days, to compact discs (CDs) and digital versatile discs (DVDs), and more recently to flash memories for storing MPEG layer 3 (MP3) audio data and MP3 players. Popularity for magnetically recorded tapes has especially waned over the years because magnetic media are demagnetized easily, thereby shortening their lifetimes, and furthermore have relatively small recording capacities.

MP3 audio data are compressed and stored in semiconductor memories, such as read-only memories (ROMs), erasable programmable read-only memories (EPROMs), or flash memories. Hence, an MP3 audio file usually occupies around 3 to 5 megabytes of memory, which is considerably smaller than that of a CD audio file. The music fidelity of the decoded MP3 audio data is good enough for most users. Consequently, many users convert CD audio data to MP3 audio data and store the data in computers that have MP3 players or in portable MP3 players. The MP3 players decode MP3 audio data and broadcast music.

MP3 players and other digital music players possess many advantages, like being small and lightweight. Many such players have hard disk drives which allow a user's entire music collection to be stored on a pocketsized device. However, such a characteristic of portability entails that the speakers equipped with the digital music players are also small, making compressed digital music, such as MP3 music, unlikely to be broadcasted publicly. Presently, personal digital audio players are portable stand-alone units that allow a user to enjoy digital quality music with headphones or portable speakers. Many users of similar devices have a desire to listen to the digital audio player recorded music, while driving in an automobile. It can be dangerous to listen to headphones while driving and an alternative is to use a standard FM radio so that the automobile speaker system is utilized to listen to high quality digital music. Only the most expensive car radios have accessible inputs which accept the digital audio player's output. In older car radios with cassette tape players, adapters are sometimes used which fool the player into thinking a tape is in the cassette slot. In the slot is a small recoding head which makes a magnetic connection to the tape players play head. Such devices sacrifice play quality, battery life, and are problematic as most newer car radios have CD players and no tape slot. As such, there is a need for an apparatus that can receive audio signals from the digital audio player and transmit these signals through a standard FM radio. If an FM transmitter is connected to an MP3 player, for example, the player's internal battery can be drained quite quickly and require its own battery. Conventional FM transmitters in such applications may obtain operating power from a vehicle's cigarette lighter or accessory socket.

It is also true that these portable devices may be used in a home environment and played through the home's FM receiver and audio system or they may be used, at another instant, as a personal player. When used as a personal player, headphones would likely be used, thus obviating the need to transmit an RF signal. It would be desireable, then, to disable the FM transmitter when headphones are connected, thus preserving battery life and avoiding a potential for FM interference.

Because of the prevalence of MP3 type players that may be used either in an automobile with an FM transmitter, in a non-automobile setting using an FM transmitter or as a personal device using attached headphones or speakers, the Federal Communications Commission (FCC) of the United States has established different measurement criteria for FM transmitter radiation for use in an automobile or use outside an automobile. Radiation measurements are specified to be made of the field strength at a distance of three meters from a radiating device. Since the FCC bases the measurement criteria on the realistic use of a device, the measurement criteria for a device only to be used in an automobile may be three meters from the automobile while the measurement criteria for a device to be used outside an automobile must be three meters from the device. This difference in measurement method allows the power radiated from the transmitter to be increased by approximately 6 dB when it can be shown that the device is to be operated only in an automobile. It is clear, then, that an opportunity exists to more finely optimize operation of portable MP3-like devices.

The MP3 music and MP3 players mentioned are only examples to illustrate the embodiments conveniently and are not proposed to limit the present invention. The apparatus according to the invention can adapt to or integrate with other types of digital music players as well as modulate other formats of compressed digital music, such as that of code excited linear prediction (CELP), window media audio (WMA), and advanced audio coding (AAC), without departing from the scope and the spirit of the invention. Although we generally refer to auto or automobile, it should be understood that these terms are intended to encompass a broad range of vehicular conveyance.

### SUMMARY OF THE INVENTION

In accordance with one aspect of the present invention, there is provided an apparatus comprising a transmitter configured to transmit a radio frequency signal at a first transmitted power level or a second transmitted power level, and a detector configured to operate the transmitter at the first transmitted power level when the apparatus is operating from a first source of operating power or to operate the transmitter at the second transmitted power level when the apparatus is operating from a second source of operating power. In one embodiment the first source of operating power is an automobile power source. A detector may be used to determine operation from the automobile power source by sensing connection of the apparatus to a first type of connector or the detector may determine operation from the automobile power source by sensing a voltage level at an input power connection.

Another embodiment of the invention is a method of operation comprising the steps of detecting connection of a transmitting device to one of a first source of operating power or a second source of operating power; and operating the transmitting device at a first transmitting power level when the transmitting device is connected to the first source of operating power and operating the transmitting device at a second transmitting power level when the transmitting device is connected to the second source of operating power.

A further embodiment of the invention comprises transmitter means configured to transmit a radio frequency signal at a first transmitted power level or a second transmitted power level and detecting means configured to operate said transmitter at the first transmitted power level when the apparatus is operating from a first source or to operate the transmitter at the second transmitted power level when the apparatus is operating from a second source.

### BRIEF DESCRIPTION OF THE DRAWINGS

For a better understanding of the present invention, reference is made to the accompanying drawings. Reference numbers refer to the same or equivalent parts of the present invention throughout the several figures of the drawings.

FIGS. 1 and 2 describe two different views of an embodiment of an audio player having integral transmitter and cigarette lighter plug.

FIG. 3 describes in block diagram and schematic form, a system for disabling a transmitter when headphones are connected, for increasing the radiated RF signal from an included FM transmitter when the portable device is used in an automobile environment and for selecting various radiating elements.

FIGS. 4 and 5 show details of a headphone jack with an integral switch for detecting a plug not inserted (FIG. 4) or a plug inserted (FIG. 5) into an audio output jack.

FIG. 6 details, in block diagram form, an alternative circuit for detection of connection of headphones.

FIGS. 7 and 8 demonstrate examples of an embodiment of a cigarette lighter plug for detecting if the plug is not inserted in a receptacle (FIG. 7) or is inserted in a receptacle (FIG. 8).

FIGS. 9 and 10 are block diagrams helping to explain the radiation mechanisms of some embodiments of the invention.

FIG. 11 shows a flow chart of a method of disabling a transmitter associated with a portable audio device when headphones are connected to the device.

FIG. 12 shows a flow chart of a method of adjusting the power of a transmitter depending on the environment of operation of an audio player and transmitter.

### DETAILED DESCRIPTION OF THE PREFERRED EMBODIMENTS

For broadcasting MP3 audio in an automobile or other environments by means of a transmitter to automobile or more stationary receiving equipment, the apparatus and methods for vehicles in accordance with the preferred embodiments of the present invention are disclosed in detail as follows, taken in conjunction with the accompanying drawings.

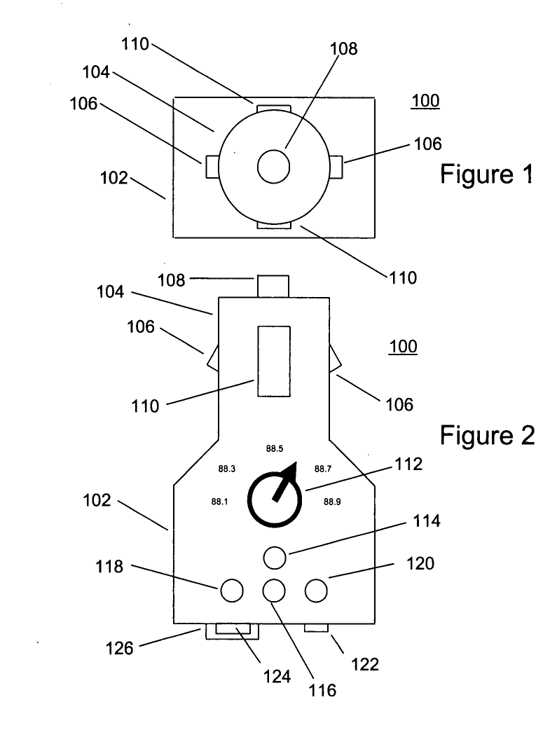

FIG. 1 shows an end view of audio player 100 which is housed in a case 102 which has an integral cylindrical cigarette lighter type plug 104. Contained within plug 104 are retaining ears 106 for holding plug 104 in place when inserted into a mating socket. Also co-axial to plug 104 is a spring-loaded positive power connector 108 and negative supply terminals 110. FIG. 2 is a front view of audio device 100 and shows, in addition to features 102-110, a transmitter frequency selector 112, operational controls 114-120, a headphone output connector 122, a memory card 124 containing audio source material and a Universal Serial Bus connector 126 for alternative audio source data.

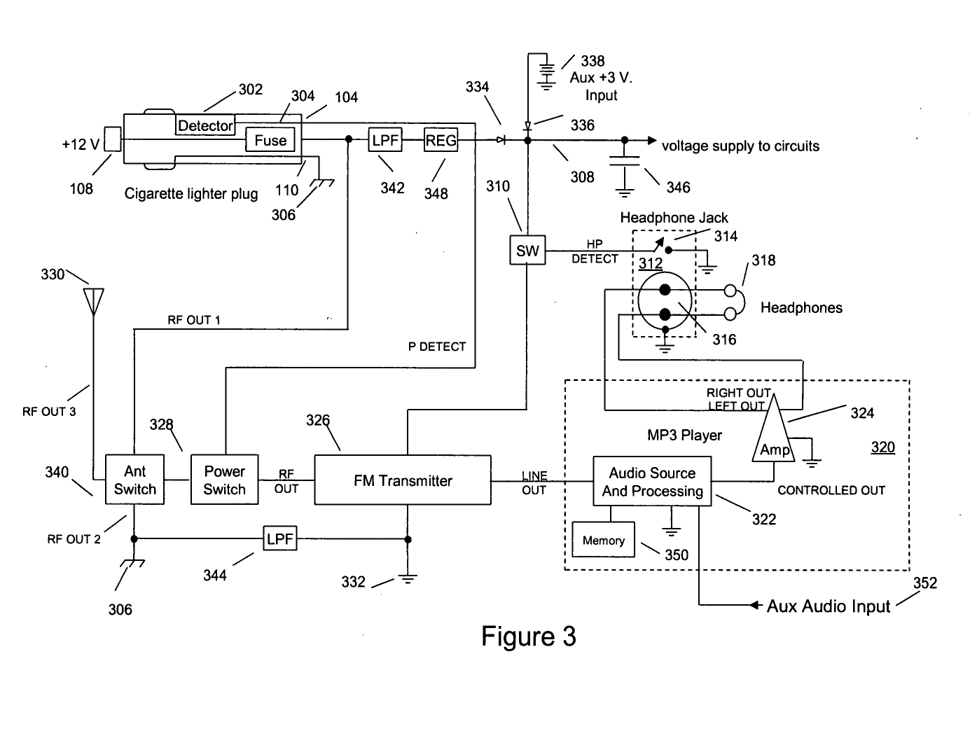

Looking now to FIG. 3, cigarette lighter plug 104 is shown to contain +12 V. plunger 108, a detector 302 and a fuse 304. When plug 104 is inserted into a mating socket, in one embodiment plunger 108 makes contact with the 12 volt power system of the vehicle. When plug 104 is inserted into a mating socket, +12 volts from the vehicle power system powers voltage regulator 348 which provides, usually, about +5 volts to power included circuits. The voltage output from regulator 348 forward biases diode 334 and provides operating voltage to the audio and transmitter circuits. If the portable device is operated from an internal 3 volt battery, or equivalent, 338, and +12 volts is not applied to plunger 108, diode 336 is forward biased, supplying operating voltage. In this way, battery 338 is used only when plunger 108 is not providing input power. As plunger 108 is compressed against an internal spring, detector 302 senses insertion of the plug 104 into the socket. A signal, P DETECT, is output from detector 302 and signals power switch 328 to increase the RF power delivered to antenna switch 340 when plug 104 is inserted in its mating socket. Power switch 328 may operate in any of a number of ways known to those skilled in the art; such as a gain controlled amplifier, a switched attenuator or a switched capacitor interposed between the transmitter 326 and antenna switch 340. Plug 104 also contains vehicle ground connection 110 to connect the portable device to the vehicle ground 306. Detector 302 could also operate by detecting compression of ground contacts 110 or by electrically detecting the presence of the 12 volt supplied from plunger 108. Audio source device 320, for example an MP3 player, contains audio source and processing circuitry 322 and amplifier 324. Audio source and processing device 322 may use SD, MMC or USB source data from a memory 350 or from an Aux audio input 352. Audio source device 320 outputs a line level output, LINE OUT, as an input to FM transmitter 326 and a volume controlled output, CONTROLLED OUT, to amplifier 324. Amplifier 324 is a headphone driver amplifier, its output signals RIGHT OUT and LEFT OUT being connected to headphone jack 312. Headphone jack 312 in one embodiment is of a type having a switch 314 to mechanically sense if a headphone plug is inserted. If headphones 318 are inserted, this condition is signaled to switch 310 by the signal HP DETECT. Switch 310 operates to apply operating voltage to FM transmitter 326 when no headphones are connected to headphone jack 312 and to remove operating voltage from transmitter 326 when headphones are connected. Audio source device 320 and FM transmitter 326 are powered from operating voltage supply 308 and circuit ground 332. Capacitor 346 is a power supply bypass capacitor for the audio source device 320, FM transmitter and other related processing circuits. Low-pass filters (LPF) 342 and 344 may be used to isolate the automobile DC power source, as input by plug 104, at RF frequencies to facilitate use of the automobile +12 volt wiring or the automobile's chassis, which is connected to the negative terminal of the automobile DC power source, as RF radiating elements in some embodiments. Antenna switch 340 is used in some embodiments to select among the automobile's +12 volt wiring, the automobile's chassis or a separate antenna 330 as the RF radiating element for the FM transmitter. Antenna switch 340 may route signals RF OUT 1, RF OUT 2 or RF OUT 3 to selected radiators.

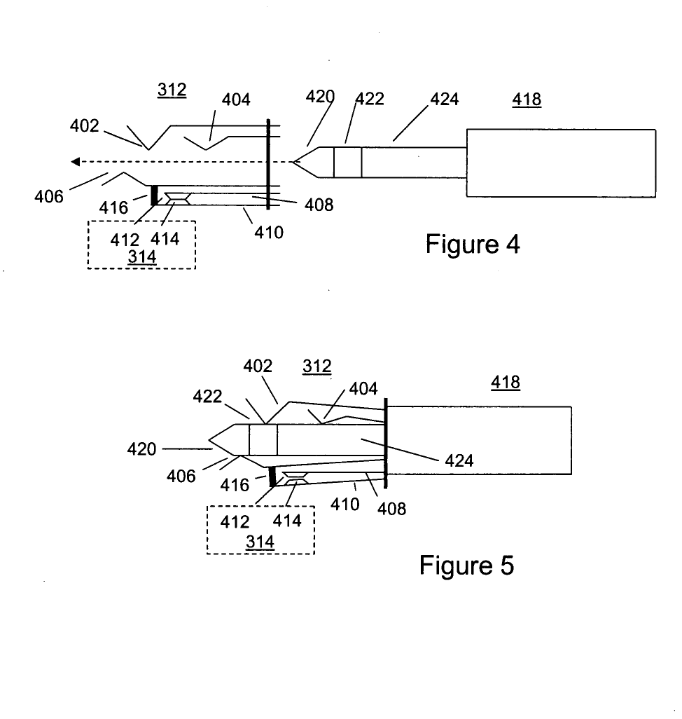

FIGS. 4 and 5 detail the construction of headphone jack 314. In FIG. 4 headphone plug 418 is not inserted into jack 314 and in FIG. 5, jack 314 and plug 418 are mated. In FIG. 4, when plug 418 is removed from headphone jack 312, switch 314 is closed and in FIG. 5, when plug 418 is inserted into jack 312, switch 314 is open. Switch 314, comprising contacts 412 and 414, is held closed when plug 418 is removed. Contacts 412 and 414 are held closed by the action of leaf spring 410 acting against rigid leaf 408. When plug 418 is inserted into jack 312, leaf spring 410 is deflected by insulator 416 which rigidly connects leaf spring 410 and spring contact 406. As switch contacts 412 and 414 are affixed to spring contact 406 and leaf spring 410 respectively, they open or close switch 314 as plug 418 is inserted or removed. Headphone jack 312 also comprises spring contact 406 for contacting tip 420 of phone plug 418, spring contact 402 for contacting ring 422 of plug 418 and spring contact 404 for contacting shank 424 of plug 418. Tip 420, ring 422 and shank 424 are connected to the left earpiece, right earpiece and ground, respectively, of headphones 318. In a monaural system, tip 420 would contact both earpieces and ring 422 would not be used. In a manner as previously described, switch 314 is opened when the plug from an external headphone 318 or speaker is inserted into the receptacle 312, and is closed when no such plug is inserted. In this manner, operating power can be removed from the FM transmitter circuit 326 if the plug of an external earphone 318 or speaker is inserted into the receptacle 312.

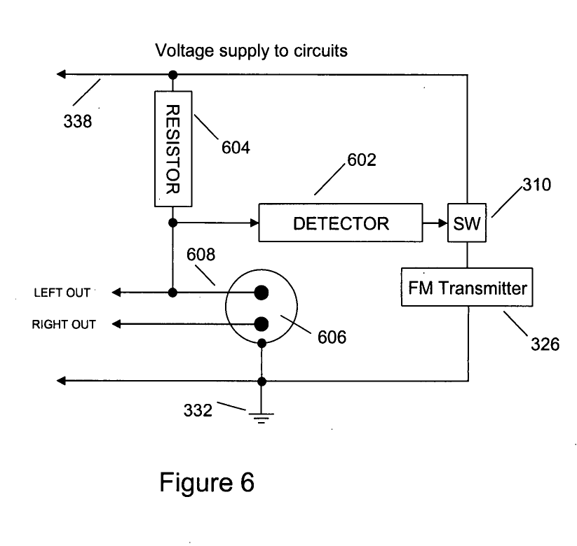

FIG. 6 illustrates an alternative embodiment for removing power from FM transmitter 326 when headset 318 is connected to output jack 606. Since jack 606 does not include a mechanical switch, in the embodiment of FIG. 6, the DC impedance of headphone 318 is measured to sense the connection. The typical DC impedance of a headphone earpiece is 32 Ohms, so by placing resistor 604 between the voltage supply 338 and the left earpiece connection 608, a detector 602 will see 12 volts at its input if no earphone is connected to jack 606 and will see a lower voltage, the divider ratio of 32 ohms to the value of resistor 604, at its input when a headphone is connected. Detector 602 output can then operate switch 310 to either apply or remove the supply voltage to FM transmitter 326. In this embodiment, connection of resistor 604 and detector 602 to the left audio output is desireable to accommodate both stereo and mono systems.

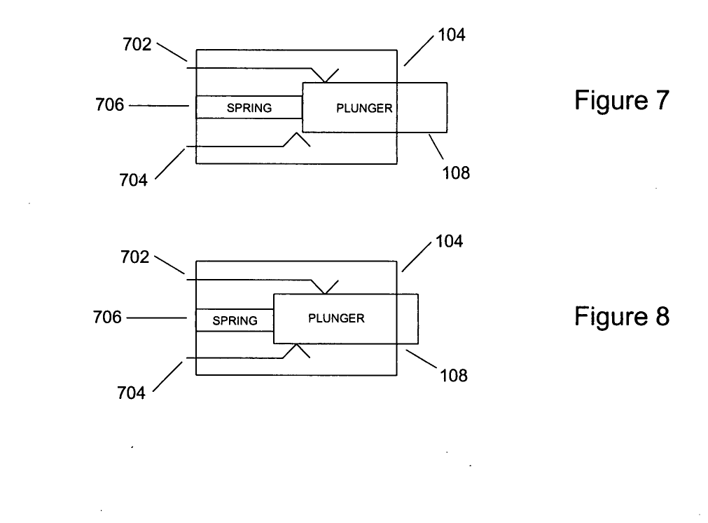

FIGS. 7 and 8 describe the details of the mechanical construction of an embodiment of detector 302 in a cigarette lighter type plug 104. Plunger 108 is shown in FIG. 7 in its neutral state wherein spring 706 has extended plunger 108 outward, as when plug 104 is not inserted into a mating socket. In the condition of FIG. 7 a switch formed by spring contacts 702 and 704 is open and no voltage is applied to either switch contacts 702 or 704. When plug 104 is inserted into a mating socket, +12 volts is applied to plunger 108 from the vehicle's battery and plunger 108 is moved into the body of plug 104, operating against spring 706. +12 volts is applied to spring contact 702 to supply operating voltage to the portable device. +12 volts is also applied to spring contact 704, which in this embodiment provides detector output P DETECT. One could develop signal P DETECT directly by detecting +12 volts supplied to the audio circuits, but by incorporating switch contact 704 to sense the compression of plunger 108, it becomes more difficult for a user to subvert the rules of allowable power by applying +12 volts to plunger 108 without inserting plug 104 into a mating socket.

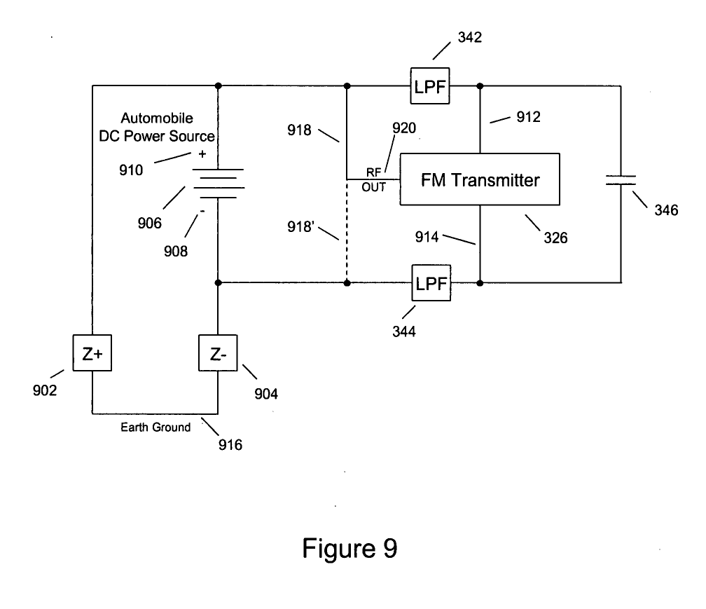

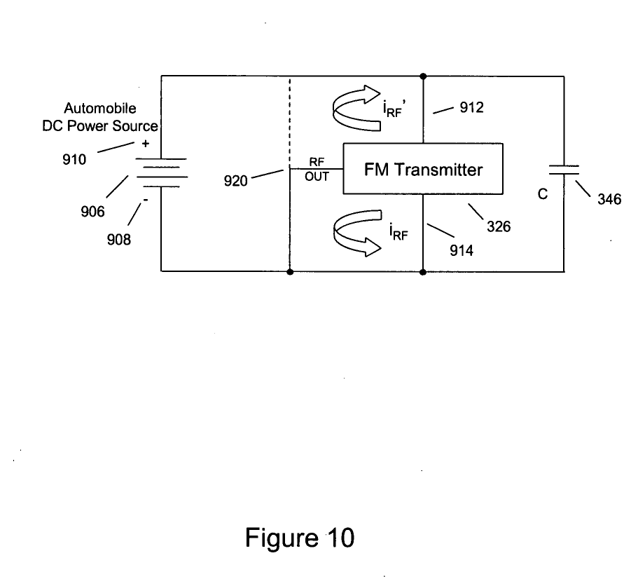

With the aid of FIGS. 9 and 10, we will describe mechanisms by which the FM transmitter 326 may radiate the RF out signal in several embodiments. In one embodiment shown in FIG. 9, low-pass filter 342 is interposed between operating supply voltage terminal 912 and the positive terminal 910 of the automobile DC power source represented as 906. The signal RF OUT 920 from FM transmitter 326 is then connected by connection 918 to automobile power source positive terminal 910. Element Z+, item 902, represents the radiation impedance between the automobile's +12 volt wiring and earth ground 916. If the impedance of LPF 342 at the frequency of signal RF OUT is significantly higher than radiation impedance 902, the auto's +12 volt wiring will be a very effective electrostatic radiating antenna. In a different embodiment, shown by dashed line 918′ connecting RF OUT from FM transmitter 326 to negative terminal 908 of DC power source 906, RF signals are coupled to negative terminal 908 of DC power source 906, isolated from operating supply voltage negative terminal 914 by LPF 344. In a manner similar to that previously presented, if the impedance of LPF 344 is large compared to the radiation impedance 904 from the automobile chassis to earth ground, then the entire car can become the radiating antenna.

In FIG. 10 the signal RF OUT is connected directly to supply voltage negative terminal 914 without the isolation of LPF 344. In this embodiment signal RF OUT produces a loop current i_{RF} flowing from FM transmitter output terminal 920 through the low impedance formed by the FM transmitter negative return connection 914 and bypass capacitor 346. This current flowing in such a low impedance loop favors generation of a magnetic field radiation antenna where the radiation from the +12 volt or chassis ground embodiments shown in FIG. 9 favors generation of an electric field. A significance of the difference in type of field favored by embodiments of FIG. 9 compared to embodiments of FIG. 10 is the rate at which field strength attenuates as a function of distance from the radiator. A magnetic field attenuates proportionally to the inverse of the cube of distance from the radiator whereas an electric field attenuates proportionally to the inverse of the square of the distance. Use of a structure that optimizes radiation of a magnetic field can allow use of a higher field strength in the immediate vicinity of the FM receiver's antenna while maintaining a prescribed level 3 meters from the automobile. Comparing equal field strength at 3 meters from the automobile from an electric field generator and from a magnetic field generator, the field strength at 1 meter from the portable device will be greater for the magnetic field generator. This is a decided benefit for the magnetic field generator since the field strength at the FM receiver's antenna is maximized while still complying with the FCC regulations. An alternative embodiment is also shown in FIG. 10 wherein the signal RF OUT is connected to the positive supply 912 of FM Transmitter 326, generating loop current i_{RF}′.

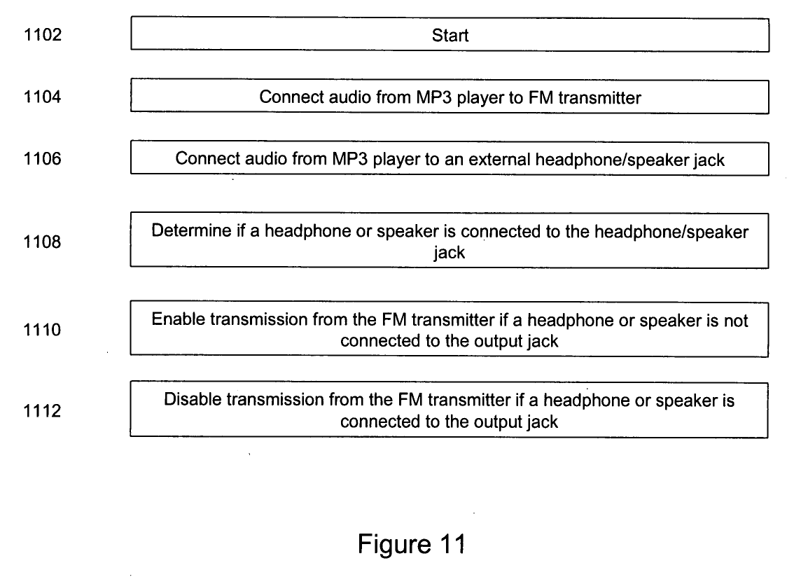

FIG. 11 describes a method of disabling a transmitter of a portable device if a headphone or speaker is connected to an output jack. The method comprises starting at step 1102, connecting audio from an audio source device to an FM transmitter at step 1104, connecting audio from an audio source device to an external headphone/speaker jack at step 1106, determining if a headphone or speaker is connected to the jack at step 1108 and enabling transmission from the transmitter if a headphone or speaker is not connected to the output jack at step 1110 or disabling transmission from the transmitter if a headphone or speaker is connected to the output jack at step 1112.

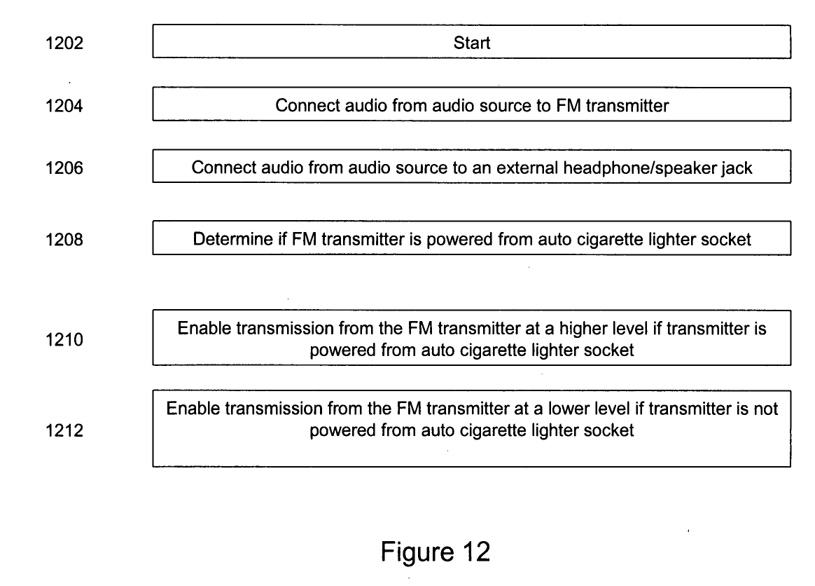

FIG. 12 describes a method of controlling the power level from a transmitter comprising starting at step 1202, connecting audio from an audio source device to an FM transmitter at step 1204, connecting audio from an audio source device to an external headphone/speaker jack at step 1206, determining if the transmitter is powered from an automobile cigarette lighter type socket at step 1208 and enabling transmission from the transmitter at a higher level if the transmitter is powered from an automobile cigarette lighter type socket at step 1210 or enabling transmission from the transmitter at a lower power level if the transmitter is not powered from an automobile cigarette lighter type socket at step 1212.

Free field radiation measurements indicate that by measuring the transmitter field strength at 3 meters from an automobile, the radiated power from the transmitter can be increased by 6 to 7 dB vertically and about 20 dB over the condition of free field radiation at 3 meters from the portable device. This provides a significant improvement in performance for operation in a vehicular environment.

While the invention may be susceptible to various modifications and alternative forms, specific embodiments have been shown by way of example in the drawings and described in detail herein. However, it should be understood that the invention is not intended to be limited to the particular forms disclosed, rather the invention is to cover all modifications, equivalents and alternatives falling within the spirit and scope of the invention as defined by the following appended claims.

1. An apparatus comprising:
a transmitter to transmit a radio frequency signal at a first power level or a second power level; and
a detector configured to operate said transmitter at said first transmitted power level when said apparatus is operating from a first source of operating power or to operate said transmitter at said second transmitted power level when said apparatus is operating from a second source of operating power.

2. The apparatus of claim 1 wherein said first source of operating power is an automobile power source.

3. The apparatus of claim 2 wherein said detector determines operation from said automobile power source by detecting connection of said apparatus to a first type of connector.

4. The apparatus of claim 2 wherein said detector determines operation from said automobile power source by detecting a voltage level at an input power connection.

5. The apparatus of claim 1 wherein said transmitter contains a frequency modulator.

6. The apparatus of claim 1 wherein a signal to modulate said transmitter is an audio signal.

7. The apparatus of claim 6 wherein said audio signal is an MP3 compressed signal.

8. The apparatus of claim 1 wherein said first power level is greater than said second power level.

9. A method of operation comprising the steps of:
detecting connection of a transmitting device to one of a first source of operating power or a second source of operating power; and
operating said transmitting device at a first power level when said transmitting device is connected to said first source of operating power and operating said transmitting device at a second power level when said transmitting device is connected to said second source of operating power.

10. The method of claim 9 further comprising the step of detecting if said transmitting device is connected to an automobile source of operating power.

11. The method of claim 10 wherein the step of detecting if said transmitting device is connected to an automobile source of operating power comprises the step of detecting connection of said transmitting device to a type of connector.

12. The method of claim 10 wherein the step of detecting if said transmitting device is connected to an automobile source of operating power comprises the step of detecting a voltage level at an input power connection.

13. The method of claim 9 further comprising the step of modulating said transmitting device with an audio signal.

14. The method of claim 13 further comprising modulating said transmitting device with an MP3 compressed audio signal.

15. The method of claim 13 further comprising frequency modulating said transmitting device.

16. The method of claim 9 wherein said first power level is greater than said second power level.

17. An apparatus comprising:
transmitter means to transmit a radio frequency signal at a first power level or a second power level; and
detecting means configured to operate said transmitter at said first power level when said apparatus is operating from a first source or to operate said transmitter at said second power level when said apparatus is operating from a second source.

18. The apparatus of claim 17 further comprising means to detect if said first source is an automobile power source.

19. The apparatus of claim 18 wherein said means to detect if said first source is an automobile power source comprises means to detect mechanical connection to an automobile power source.

20. The apparatus of claim 18 wherein said means to detect if said first source is an automobile power source comprises means to detect the presence of operating power at an automobile power source.
